(19) United States
(12) Patent Application Publication
(10) Pub. No.: US 2009/0185592 A1
(43) Pub. Date: Jul. 23, 2009

(54) Laser diode system with reduced coolant consumption

(76) Inventor: Jan Vetrovec, Larkspur, CO (US)

Correspondence Address: Aqwest LLC, P.O. BOX 468, Larkspur, CO, 80118, US

(21) Appl. No.: 12/321,226

(22) Filed: Jan. 17, 2009

Related U.S. Application Data
(60) Provisional application No. 61/011,691, filed on Jan. 18, 2008.
(60) Provisional application No. 61/066,249, filed on Feb. 19, 2008.
(60) Provisional application No. 61/130,419, filed on May 31, 2008.

(51) Int. Cl. H01S 5/024

(52) U.S. Cl. 372/35

(57) ABSTRACT

High-power laser diode system offering reduced consumption and inventory of coolant. The invention provides coolant at a very high flow rate to a heat exchanger. A portion of the coolant flow downstream of the heat exchanger is separated and pumped by a fluid-dynamic pump back into the heat exchanger. The fluid dynamic pump is operated by a fresh coolant supplied at high-pressure. Because a substantial portion of the flow leaving the heat exchanger is recirculated back to the inlet, the amount of fresh coolant consumed is substantially reduced compared to a traditional laser diode system. This enables reduced size of coolant lines and results in a more compact and lightweight system. Other uses of the invention include cooling of devices requiring heat rejection at very high heat flux including photovoltaic cells, solar panels, semiconductor laser diodes, semiconductor electronics, and laser gain medium.

### CROSS-REFERENCE TO RELATED APPLICATIONS

This application claims priority from U.S. provisional patent application U.S. provisional patent application U.S. Ser. No. 61/011,691, filed Jan. 18, 2008; U.S. provisional patent application U.S. Ser. No. 61/066,249, filed Feb. 19, 2008; and U.S. provisional patent application U.S. Ser. No. 61/130,419, filed May 31, 2008.

### FIELD OF THE INVENTION

This invention relates generally to systems for thermal management and more specifically to supplying a fluid to a heat exchanger for thermal management.

### BACKGROUND OF THE INVENTION

High-power semiconductor laser diodes are finding ever increasing industrial applications such as pumping of solid-state lasers (SSL) and direct material processing, namely cutting, welding, and heat treating. Frequently, such laser diodes are part of a system installed on a mobile mount such as a translation stage or a robotic arm. Other applications for high-power semiconductor laser diodes include a variety of electro-optical systems for a field use such as LIDAR, target illuminators, target designators, or high-energy lasers that may be operated on a land or air vehicle. In all such instances, it is essential to reduce the weight and volume of the high-power laser diode system.

As a byproduct of generating optical output, laser diodes produce large amount of waste heat. To avoid overheating, laser diodes may be mounted on a suitable heat sink. Such a heat sink may be constructed as an actively cooled heat exchanger (HEX). Suitable HEX may use microchannels or impingement cooling. To achieve their target heat transfer performance, such HEX operate at high coolant velocities around 2 to 3 m/s. This results in very high coolant consumption. At the same time, the coolant temperature rise in the HEX is only about 2-3° C., which translates to a rather low coolant utilization.

For high-power applications, multiple semiconductor laser diodes may be mounted on a common semiconductor substrate known as a bar, which is then mounted on a HEX to form a diode bar assembly. FIG. 1A shows a diode bar assembly 186 of prior art comprising a laser diode bar 146 with laser diodes 190 mounted on a HEX 182. The diodes generate optical output 114. The HEX 182 has a coolant inlet port 154 and a coolant outlet port 156. Coolant may flow into the inlet port 154, is conveyed by internal passages inside the HEX to a close proximity of the laser diode bar 146, removes waste heat from the laser diode bar, and flow out through the outlet port 156. General path of coolant flow is identified by arrows 116. Suitable diode bar assemblies may be purchased, for example, from Northrop-Grumman Cutting Edge Optronics (CEO) in Saint Charles, Mo. and from DILAS in Tuscon, Ariz.

To achieve even higher optical output, multiple diode bar assemblies may be arranged to form a diode bar stack. FIG. 1B shows a diode bar stack 130 of prior art comprising multiple diode bar assemblies 186, an inlet end cap 110, and an outlet end cap 112. The end caps have internal passages arranged to align with the inlet and outlet ports of diode bar assemblies 186. This arrangement allows for a coolant to be fed to the diode bar assemblies 186 in the stack 130 by a single end cap inlet port 192 and drained by a single end cap outlet port 196. Suitable diode bar stacks may be purchased, for example, from the already noted Northrop-Grumman CEO and DILAS.

The wavelength of laser diode output light is known to be sensitive to coolant temperature. This creates a design challenge in applications requiring wavelength stability, such as when pumping SSL where the diode wavelength must be precisely matched into an absorption band of a laser crystal. In this situation, coolant feeds to individual high-power laser diode bar assembly in an array cannot be connected in series, but rather must be connected in parallel. As a result, coolant must be supplied to such arrays at very high flow-rates to maintain the diodes at their design temperature.

Traditional high-power laser diodes employs a cooling system with a forced convection loop that transports waste heat from the diodes to a chiller or a thermal energy storage. When operating with a powerful laser diode array, large quantities of coolant may be circulated between the array and the chiller. In applications where the laser diodes and the chiller are separated by a large distance, this results in long, large size piping and large coolant inventory. In addition, when laser diodes are mounted on a translations stage or a robotic arm, heavy coolant lines present undesirable inertia and impede motion. The traditional cooling system also stresses the volume and weight carrying capacity of mobile platforms such as land and air vehicles. All such applications would greatly benefit from a cooling system operating with low coolant consumption that is lightweight and compact.

Furthermore, a traditional laser diode systems may require a large amount of coolant inventory. In the event of an accidental coolant release from the system, such a large coolant inventory may pose significant safety, health, and environmental hazards. In addition, a large coolant inventory has a large inertia, which must be overcome during flow start and stop conditions. The above size, weight, energy consumption, coolant inventory, and inertia characteristics of traditional thermal management system may make it less desirable in applications requiring compactness, lightweight, reduced energy consumption, improved safety, and fast startup.

### SUMMARY OF THE INVENTION

The subject invention provides a simple, compact, lightweight laser diode system offering reduced coolant inventory and energy consumption. In particular, the subject invention provides coolant at a very high flow rate to a laser diode HEX. A portion of the coolant flow downstream of the HEX outlet is separated and pumped by a fluid-dynamic pump back into the HEX inlet. The fluid dynamic pump is operated by a fresh coolant supplied at high-pressure that may be provided by a pump, a high-pressure tank, or other suitable source. Because a substantial portion of the flow leaving the HEX is recirculated back to the HEX inlet, the amount of fresh coolant consumed is substantially reduced compared to a traditional laser diode system. A portion of the coolant downstream of the HEX that is not recirculated back to the HEX may be fed to the suction port of a pump, or stored in a tank or an accumulator, or it may be released to environment. See, for example, a publication entitled “Improved Cooling for High-Power Laser Diodes,” authored by John Vetrovec in proceedings from Photonics West, San Jose, Calif., Jan. 20-24, 2008, SPIE vol. 6876, and “Lightweight and Compact Thermal Management System for Solid-State High-Energy Laser,” in proceedings from the 21^{st} Annual Solid-State and Diode Technology Review, held in Albuquerque, N.Mex., Jun. 3-5, 2008, both of which are hereby expressly incorporated by reference in their entirety.

If the coolant provided to the driving nozzle of the fluid dynamic pump is substantially in a gas or vapor form, the fluid dynamic pump may be an ejector. If the coolant provided to the driving nozzle of the fluid dynamic pump is substantially in a liquid form, the fluid dynamic pump may be a jet pump.

In one preferred embodiment of the subject invention, one or more laser diodes are mounted on a HEX, and an external fluid-dynamic pump recirculates portion of the coolant through external passages.

In another preferred embodiment of the subject invention, diode bar stack is connected to a recirculator containing internal fluid-dynamic pump and recirculation passages. The recirculator, which is connected to a supply of fresh coolant, then feeds coolant to the diode bar stack and drains coolant therefrom, while recirculating a portion thereof.

In yet another preferred embodiment of the subject invention, fluid dynamic pump and recirculation passages are made integral to a diode bar assembly HEX.

These and other features and advantages of the invention will be more fully understood from the following description of certain specific embodiments of the invention taken together with the accompanying drawings.

Accordingly, it is an object of the present invention to provide a lightweight and compact laser diode system.

It is another object of the invention to provide a laser diode system for reduced coolant inventory.

### BRIEF DESCRIPTION OF THE DRAWINGS

FIG. 1A is an isometric view of a laser diode bar assembly of prior art.

FIG. 1B is an isometric view of a diode bar stack of prior art.

FIG. 2 is a diagrammatic view of a laser diode system according one embodiment of the present invention.

FIG. 3 is a side cross-sectional view of a laser diode system according alternative embodiment of the present invention suitable for laser diode bar stacks.

FIG. 4 is a side cross-sectional view of a laser diode system according another alternative embodiment of the present invention suitable for a laser diode bar assembly.

FIG. 5 is a cross-sectional view 4-4 of the laser diode system in FIG. 4.

FIG. 6 is a cross-sectional view 5-5 of the laser diode system in FIG. 4.

### DETAILED DESCRIPTION OF THE PREFERRED EMBODIMENTS

Selected embodiments of the present invention will now be explained with reference to drawings. It will be apparent to those skilled in the art from this disclosure that the following descriptions of the embodiments of the present invention are merely exemplary in nature and are in no way intended to limit the invention, its application, or uses.

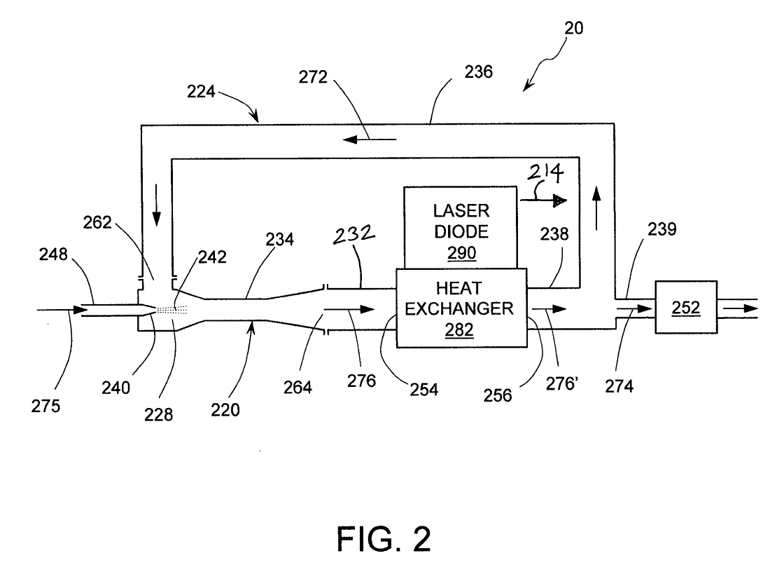

Referring to FIG. 2 of the drawings in detail, numeral 20 generally indicates a laser diode system generally comprising a fluid-dynamic pump 220, laser diode 290, heat exchanger (HEX) 282, back-pressure valve 252, return passage 236, and interconnecting passages 232, 238, and 239. The HEX 282 is in good thermal communication with the laser diode 290. The HEX 282 has an inlet port 254 and an outlet port 256. The fluid dynamic pump 220, HEX 282, return passage 236, and interconnecting passages 232 and 238 form a recirculation loop 224. In general, the fluid-dynamic pump 220 is arranged to feed a suitable coolant to the inlet port 254 of the HEX 282 and to recirculate a portion of coolant flowing from the outlet port 256 back to the inlet port 254 of the HEX 282. The fluid-dynamic pump 220 further comprises a driving nozzle 240 and a pump body 234. The pump body 234 is generally configured as a duct including a suction chamber 228. The pump body 234 may also include a converging portion, which may be followed by followed by a straight portion, which may be followed by a diverging portion. The suction chamber 228 includes a suction port 262. The downstream portion of the pump body 234 has a discharge port 264. The suction port 262 of fluid dynamic pump 220 is fluidly connected to the return passage 236. The discharge port 264 of fluid dynamic pump 220 is fluidly connected to the inlet port 254 of heat exchanger 282 by means of the passage 232. The back pressure valve 252 is fluidly connected to the outlet port 256 of heat exchanger 282 by means of passages 238 and 239. The return passage 236 is also fluidly connected to the outlet port 256 of heat exchanger 282 by means of the passage 238. The driving nozzle 240 is of fluid-dynamic pump 220 arranged to discharge high-velocity flow (et) 242 into the throat of the pump body 234. This arrangement is common in fluid dynamic pumps. The driving nozzle 240 is fluidly connected by means of a supply line 248 to a source of high-pressure coolant. The back pressure valve 252 is arranged to provide a flow impedance to coolant flowing therethrough. One advantage of the back pressure valve 252 is its adjustability. In a variant of the invention not requiring adjustability, alternative flow-impeding device such as an orifice or a venture may be used.

If the heat transfer fluid is gas, the fluid dynamic pump may be an ejector. Suitable ejectors with a single driving nozzle are Series 20A ejectors made by Penberthy, Prophetstown, Pa. Alternative ejectors may have multiple driving nozzles and/or lobed driving nozzles. If the heat transfer fluid is liquid, the fluid dynamic pump may be a hydraulic ejector also known as a jet pump. Suitable hydraulic ejectors with a single driving nozzle are Series 60A ejectors made by Penberthy, Prophetstown, Pa. Alternative hydraulic ejectors may have multiple driving nozzles and/or lobed driving nozzles.

In operation, the fluid dynamic pump 220, HEX 282, return passage 236, and interconnecting passages 232, 238 and 239 are substantially filled with suitable coolant. The laser diode 290 is connected to a source of electric power and generates optical output 214. As a by-product of generating optical output, the laser diode 290 generates heat that is conducted to HEX 282. High-pressure coolant is supplied by a stream 275 via the supply line 248 to the driving nozzle 240 where it forms a jet 242 that is directed into the throat portion of the pump body 234. The jet 242 entrains coolant in the suction chamber 228 and pumps it. Stream 276 containing both the jet flow and the pumped coolant exits the fluid dynamic pump 220 through the discharge port 264 and flows through the passage 232 into the inlet port 254 of HEX 282. The coolant removes heat from the HEX 282 and exits the HEX 282 through the outlet port 256 as a stream 276′ flowing in the passage 238. A portion of the coolant stream 276′ is separated and directed as a recirculating stream 272 into the return passage 236. The un-separated portion of the stream 276′ forms an exit stream 274 that is released from the laser diode system 20 through he back pressure valve 252. The back pressure valve 252 may be adjusted so that a large portion of the stream 276′ is directed in the form of the recirculating stream 272 into the return passage 236. As a result, a large flow may be maintained through the HEX 282 while the overall consumption of fresh coolant as, for example, measured by the flow in the stream 275 fed to the driving nozzle 240 is substantially smaller. Coolant supplied to the nozzle 240 may be provided at a temperature such that the stream 276 (which is a mixture of nozzle flow and the stream 272) fed to the HEX 282 is provided at a predetermined temperature value. In particular, if the coolant is a gas, this gas provided in the line 248 may be chilled in a heat exchanger, a vortex tube, or a turboexpander prior to being fed to nozzle 240. Temperature of laser diode 290 may be controlled by appropriately adjusting the backpressure valve 252. An alternative method for controlling the temperature of laser diode 290 may be achieved by appropriately adjusting the pressure of coolant supplied to the nozzle 240.

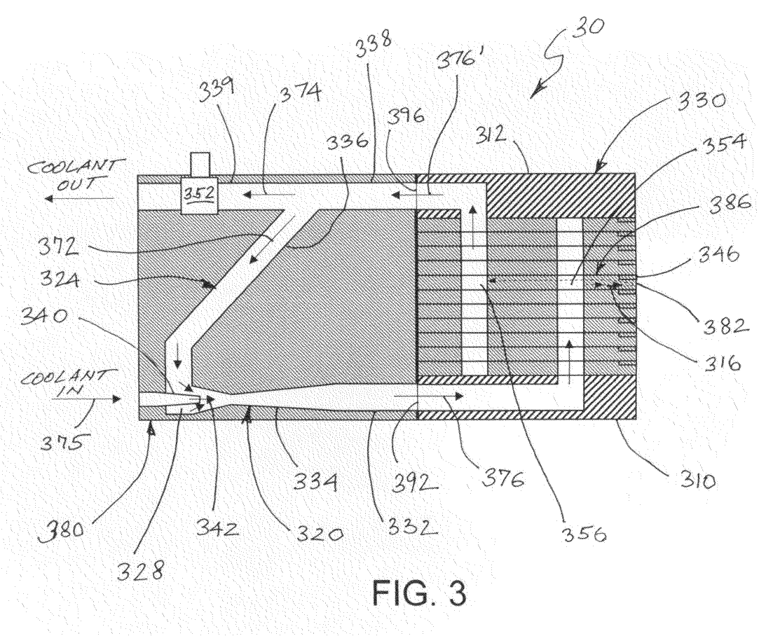

An alternative embodiment of the invention is particularly suitable for use with diode bar stacks. Referring now to FIG. 3, there is shown a cross-sectional view of a laser diode system 30 comprising a diode bar stack 330 connected to a coolant saving recirculator 320. The laser diode system 30 is similar to the laser diode system 20 except that the laser diodes are now arranged into diode bar assemblies 386 installed in a diode bar stack 330, and the fluid dynamic pump with the backpressure valve and the passages are now integrated into the recirculator 320.

The recirculator 320 includes a fluid dynamic pump 320, return passage 336, a backpressure valve 352, and interconnecting passages 332, 338, and 339. The recirculator may be machined from a block of suitable material (such as metal, plastic, or ceramic) and the fluid dynamic pump, return passage, backpressure valve, and interconnecting passages may be formed therein. The passage 332 of recirculator 330 is arranged to fluidly couple to the end cap inlet port 392. The passage 338 of the recirculator 330 is arranged to fluidly couple to the end cap outlet port 396.

In operation, the fluid dynamic pump 320, return passage 236, and interconnecting passages 332, 338, and 339 as well as the internal passages and HEX of the diode bar stack 330 are substantially filled with suitable coolant. The diode bar assemblies 386 are connected to a source of electric power and generates optical output. As a by-product of generating optical output, the diode bar assemblies 386 generate heat that is conducted to HEX 382. High-pressure coolant is supplied by a stream 375 to the driving nozzle 340 where it forms a jet 342 that is directed into the throat portion of the pump body 334. The jet 342 entrains coolant in the suction chamber 328 and pumps it. Stream 376 containing both the jet flow and the pumped coolant exists the fluid dynamic pump 320 and flows through the passage 332 into the end cap inlet port 392, and therefrom to the inlet ports 354 of HEX 382. The coolant removes heat from the HEX 382 and laser diode bars 346 attached thereto, exits the HEX 382 through the outlet port 356, and flows out of the diode bar stack 330 through the end cap outlet port 396 as a stream 376′ flowing in the passage 338. A portion of the coolant stream 376′ is separated and directed as a recirculating stream 372 into the return passage 336. The un-separated portion of the stream 376′ forms an exit stream 374 that is released from the laser diode system 30 through the back pressure valve 352.

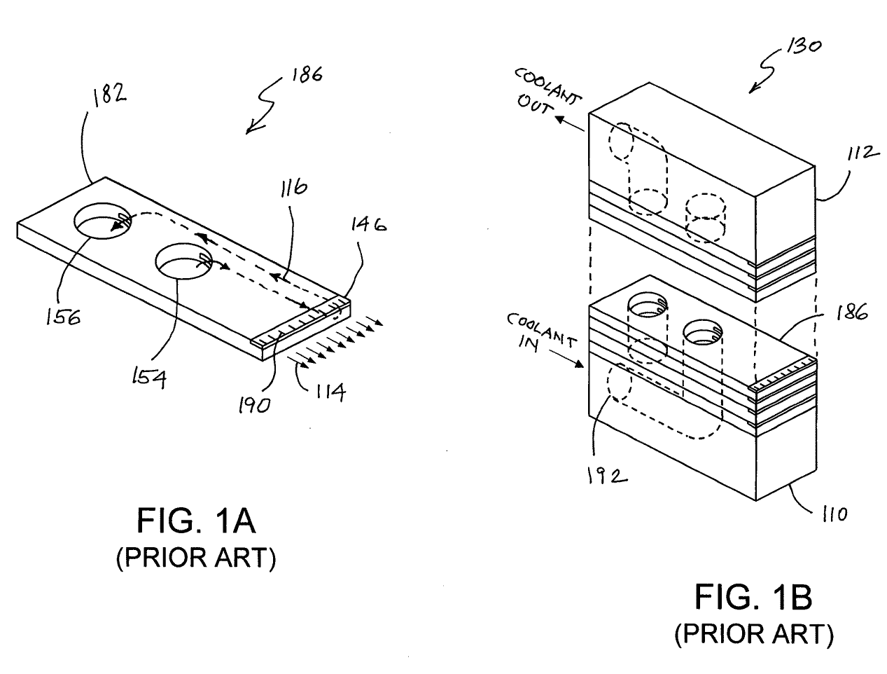

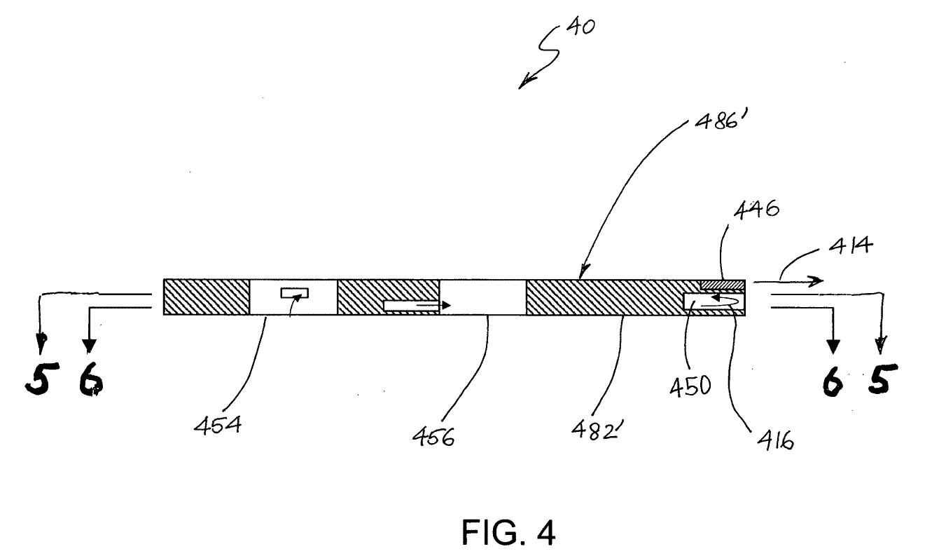

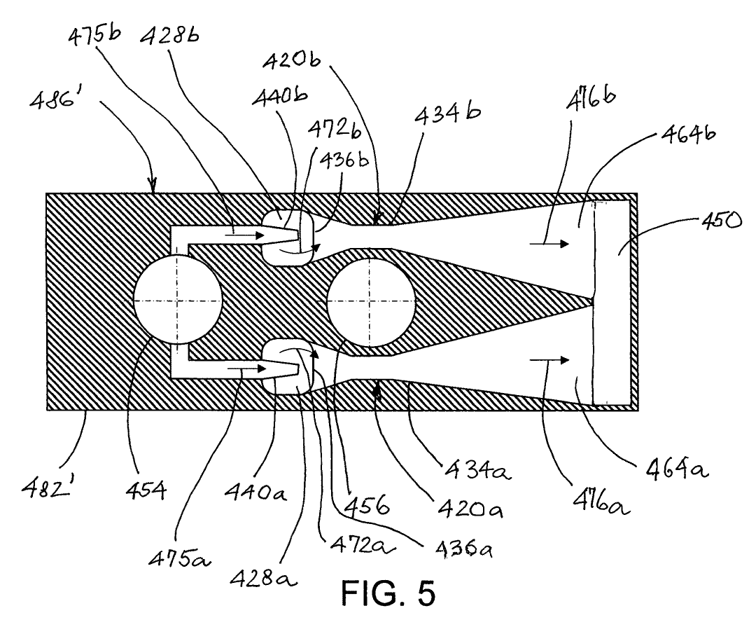

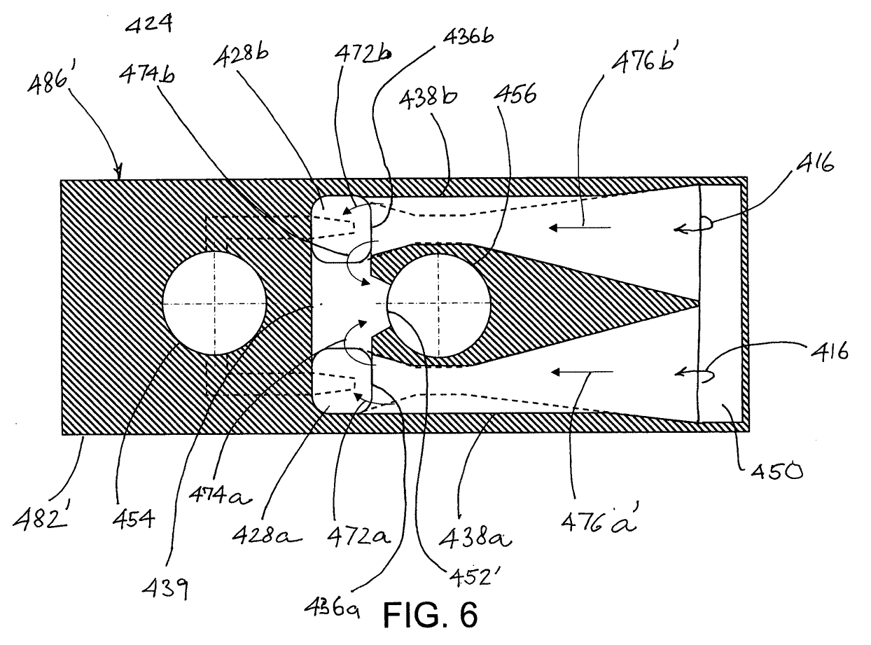

Another alternative embodiment of the invention is particularly suitable for use with diode bar assemblies. Referring now to FIG. 4, there is shown a laser diode system 40 comprising a diode bar assembly 486′ including a laser diode bar 446 attached to a HEX 482′ having a coolant inlet 454 and a coolant outlet 456. The diode bar assembly 486′ is similar to the diode bar assembly 186 shown in FIG. 1A, except that the HEX 482′ now comprises two internal fluid dynamic pumps 420a and 420b and associated internal coolant passages (FIGS. 5 and 6).

In particular, FIG. 5, which is a cross-section through the diode bar assembly 486′ generally in the plane of the fluid dynamic pumps 420a and 420b, shows fluid dynamic pumps 420a and 420b respectively having nozzles 440a and 440b each fluidly connected to coolant inlet port 454 and respectively positioned inside suction chambers 428a and 428b. Nozzles 440a and 440b are respectively directed respectively into the throats of body 434a and fluid dynamic pumps 420a and 420b. Discharge ports 464a and 464b are fluidly coupled into zone 450 that is in a close proximity of the laser diode bar 446 (FIG. 4). The zone 450 may comprise surface extensions, microchannels, or impingement jet coolers to promote heat transfer from laser diode bar 446 into the coolant flowing through zone 450.

Referring now to FIG. 6, there is shown a cross-section through the diode bar assembly 486′ generally in the plane of the passages 438a and 438b. The passages 438a and 438b respectively fluidly connect the zone 450 to the suction chambers 428a and 428b via passages 436a and 436b. The passages 438a and 438b also fluidly connect the zone 450 to the outlet port 456 via passage 439 and the orifice 452′. The orifice 452′ is used in lieu of a valve and it is sized to provide appropriate impedance to the flow.

In operation, all of the internal volumes of HEX 482′ are substantially filled with coolant. The laser diode bar 446 is connected to a source of electric power and generates optical output 414. As a by-product of generating optical output, the laser diode bar 446 generates heat that is conducted to at least one wall of the zone 450 of the HEX 482′. High-pressure coolant streams 475a and 475b are supplied by the inlet port 454 to the respective driving nozzles 440a and 44b where they forms jet directed into the throat portion of the pump bodies 434a and 434b (FIG. 5). The jets respectively entrain coolant in the suction chambers 428a and 428b, and pump it. Streams 476a and 476b containing both the jet flow and the pumped coolant exit their respective fluid dynamic pumps 420a and 420b through their respective discharge ports 464a and 464b into the zone 450. After acquiring heat in zone 450, coolant flows through passages 438a and 438b respectively as streams 476a′ and 476b′. At the end of each passage 438a and 438b each respective flow 476a′ and 476b′ is divided into respective streams 472a and 474a, and 472b and 474b. Stream 472a flows through the passage 436a into the suction chamber 428a, and stream 472b flows through the passage 436b into the suction chamber 428b. Streams 472a and 472b each flow into the passage 439 and through orifice 452′ into the outlet port 456.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” and “includes” and/or “including” when used in this specification, specify the presence of stated features, integers, steps, operations, elements, and/or components, but do not preclude the presence or addition of one or more other features, integers, steps, operations, elements, components, and/or groups thereof.

HTF suitable for use with the subject invention include 1) liquids such as water, aqueous solution of alcohol, antifreeze, and oil, 2) gases including air, helium, natural gas, and nitrogen, and 3) vapors such water steam, Freon, and ammonia.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

Moreover, terms that are expressed as “means-plus function” in the claims should include any structure that can be utilized to carry out the function of that part of the present invention. In addition, the term “configured” as used herein to describe a component, section or part of a device includes hardware and/or software that is constructed and/or programmed to carry out the desired function.

While only selected embodiments have been chosen to illustrate the present invention, it will be apparent to those skilled in the art from this disclosure that various changes and modifications can be made herein without departing from the scope of the present invention as defined in the appended claims. Furthermore, the foregoing description of the embodiments according to the present invention are provided for illustration only, and not for the purpose of limiting the present invention as defined by the appended claims and their equivalents. Thus, the scope of the present invention is not limited to the disclosed embodiments.

What is claimed is:

1. A laser diode system comprising:
(a) A semiconductor laser diode;
(b) a heat exchanger being in a thermal communication with said laser diode, said heat exchanger having an inlet for receiving coolant and outlet for discharging coolant; and
(c) a fluid dynamic pump having a driving nozzle fluidly connected to a source of high-pressure coolant, a suction port fluidly connected to said outlet port of said heat exchanger, and a discharge port fluidly connected to said inlet port of said heat exchanger.

2. The laser diode system of claim 1 further comprising a means for releasing excess coolant, said means fluidly connected to said outlet of said heat exchanger.

3. The laser diode system of claim 2 wherein said means to remove excess coolant include a flow-impeding element.

4. The laser diode system of claim 2 wherein said flow-impeding element is selected from the group consisting of a backpressure valve, an orifice, and a venturi.

5. The laser diode system of claim 1 wherein said coolant is fed to said driving nozzle in a substantially liquid form.

6. The laser diode system of claim 1 wherein said coolant is fed to said driving nozzle in a substantially gaseous form.

7. The laser diode system of claim 1 wherein said laser diode is arranged in a laser diode bar.

8. The laser diode system of claim 1 wherein said laser diode is arranged in a diode bar stack.

9. A laser diode system comprising a plurality of semiconductor laser diodes, a heat exchanger (HEX), a fluid dynamic pump, and a flow-impeding element;
(a) said laser diodes being arranged in a laser diode bar;
(b) said HEX being in a thermal communication with said laser diode bar;
(c) said HEX having and inlet port and an outlet port;
(d) said fluid dynamic pump having a driving nozzle, suction port, and a discharge port;
(e) said driving nozzle being fluidly connected to a supply of coolant;
(f) said discharge port being fluidly connected to said inlet port of said HEX;
(g) said suction port of said fluid dynamic pump being fluidly connected to said outlet port of said HEX; and
(h) said flow-impeding element being fluidly connected to said outlet port of said HEX and adapted for releasing excess coolant.

10. The laser diode system of claim 9 wherein said flow-impeding element is selected from the group consisting of a backpressure valve, an orifice, and a venturi.

11. The laser diode system of claim 9 wherein said HEX is provided to said driving nozzle in a substantially liquid form.

12. The laser diode system of claim 9 wherein said HTF is provided to said driving nozzle in a substantially gaseous form and said driving nozzle of said fluid dynamic pump is a supersonic nozzle.

13. The laser diode system of claim 9 wherein said laser diode bar is arranged in a diode bar stack.

14. The laser diode system of claim 9 wherein said fluid dynamic pump is made integral with the HEX.

15. The laser diode system of claim 9 wherein said fluid dynamic pump is arranged in a recirculator.

16. A method for cooling semiconductor laser diode comprising the acts of:
(a) presenting a semiconductor laser diode;
(b) presenting a source of coolant;
(c) presenting a heat exchanger having an inlet for receiving coolant and outlet for discharging coolant;
(d) presenting a fluid dynamic pump having a driving nozzle fluidly connected to said source of coolant, a suction port fluidly connected to said outlet port of said heat exchanger, and a discharge port fluidly connected to said inlet port of said heat exchanger;
(e) presenting a means for releasing said coolant from said outlet of said heat exchanger;
(f) operating said semiconductor laser diode;
(g) conducting waste heat from said semiconductor laser diode to said heat exchanger;
(h) feeding a coolant from said source of coolant under pressure into said driving nozzle to produce a pumping action in said fluid dynamic pump;
(i) admitting said coolant into said suction port;
(j) pumping said coolant with said fluid dynamic pump;
(k) feeding said coolant from said discharge port to said inlet port of said heat exchanger;
(l) transporting heat from said heat exchanger to said coolant;
(m)flowing said coolant from said heat exchanger through said outlet port; and
(n) feeding a portion of said coolant flowing from said heat exchanger through said outlet port into said suction port of said fluid dynamic pump.

17. The method of claim 16 further including the act of releasing excess coolant through a flow impeding device.

18. The method of claim 17 further including the act of controlling the temperature of said semiconductor laser diode by adjusting the pressure of said coolant by said flow impeding device.

19. The method of claim 16 further including the act of controlling the temperature of said semiconductor laser diode by adjusting the pressure of said coolant fed to said driving nozzle.

20. The method of claim 16 wherein said semiconductor laser diode is arranged in a laser diode bar.
